(19) United States
(12) Patent Application Publication
(10) Pub. No.: US 2019/0206963 A1
(43) Pub. Date: Jul. 4, 2019

(54) DISPLAY PANEL AND METHOD FOR MANUFACTURING THE SAME

(71) Applicant: SHENZHEN CHINA STAR OPTOELECTRONICS SEMICONDUCTOR DISPLAY TECHNOLOGY CO., LTD., Shenzhen (CN)

(72) Inventors: Liangfen ZHANG, Shenzhen (CN); Jangsoon IM, Shenzhen (CN)

(21) Appl. No.: 15/945,381

(22) Filed: Apr. 4, 2018

Related U.S. Application Data
(63) Continuation of application No. PCT/CN2018/074095, filed on Jan. 25, 2018.

(30) Foreign Application Priority Data
Dec. 29, 2017 (CN) 201711481256.9

(51) Int. Cl. H01L 27/32; H01L 51/52; H01L 51/56

(52) U.S. Cl. CPC H01L 27/3262; H01L 27/3258; H01L 27/3248; H01L 27/3246; H01L 27/1248; H01L 51/5253; H01L 51/56; H01L 51/5284; H01L 2227/323; H01L 27/3272

(57) ABSTRACT

A display panel is provided, which includes a substrate; a thin film transistor disposed on the substrate; a flat layer disposed on the thin film transistor; an anode disposed on the flat layer and penetrating the flat layer to be connected to the thin film transistor; a pixel definition layer disposed on the flat layer; a light shading layer disposed on the pixel definition layer, the light shading layer and the pixel definition layer having a pixel definition aperture exposing the anode; an OLED functional layer disposed on the exposed anode; a cathode disposed on the light shading layer and the OLED functional layer. The problem of light leakage of the pixel in the prior art can be eliminated and the display effect of the display panel can be improved.

### RELATED APPLICATIONS

The present application is a Continuation Application of International Application Number PCT/CN2018/074095, filed Jan. 25, 2018, and claims the priority of China Application No. 201711481256.9, filed Dec. 29, 2017.

### FIELD OF THE DISCLOSURE

The disclosure relates to a display technical field, and more particularly, to a display panel and a method for manufacturing the same.

### BACKGROUND

In recent years, Organic Light-Emitting Diode (OLED) display panels have become very popular new flat display panel products at home and abroad, due to its characteristics of being self-luminous, wide viewing angle, short reaction time, high luminous efficiency, wide color gamut, thin thickness, large size and being flexible. The OLED display panels have simple process and the potential of low cost.

For large size and high resolution OLED display panels, the top emission structure can meet the requirement of aperture ratio. However, no matter which manufacturing process is used, there exist a problem of light leakage of the pixel (i.e. OLED functional layer), and thus the OLED display panels have a defect in displaying.

### SUMMARY

In view of above problems in prior art; the present application provides a display panel and a method for manufacturing the same for eliminating the light leakage of the OLED functional layer.

According to an aspect of the present application; a display panel is provided, which comprises: a substrate; a thin film transistor disposed on the substrate; a flat layer disposed on the thin film transistor; an anode disposed on the flat layer and penetrating the flat layer to be connected to the thin film transistor; a pixel definition layer disposed on the flat layer; a light shading layer disposed on the pixel definition layer; wherein the light shading layer and the pixel definition layer have a pixel definition aperture in the light shading layer and the pixel definition layer for exposing the anode; an OLED functional layer disposed on the exposed anode; and a cathode disposed on the light shading layer and the OLED functional layer.

In an embodiment, the thin film transistor comprises: an active layer disposed on the substrate; a first insulating layer disposed on the active layer; a gate electrode disposed on the first insulating layer; a second insulating layer disposed on the gate electrode; the active layer and the substrate; a source electrode and a drain electrode disposed on the second insulating layer, each of the source electrode and the drain electrode penetrating the second insulating layer to be connected to the active layer, wherein the flat layer is disposed on the source electrode, the drain electrode and the second insulating layer, and the anode penetrates the flat layer to be connected to the drain electrode.

In an embodiment, the OLED functional layer includes in order form the anode to the cathode: a hole generation layer, a hole transport layer, an organic light emitting layer; an electron transport layer and an electron injection layer.

In an embodiment, the display panel further comprises a cover disposed on the cathode on the light shading layer.

In an embodiment, the light shading layer is made of a black resin.

According to another aspect of the present application, a method for manufacturing a display panel is provided, which comprises: forming a thin film transistor on a substrate; forming a flat layer on the thin film transistor; forming on the flat layer an anode penetrating the flat layer to be connected to the thin film transistor; forming a pixel definition layer on the flat layer and the anode; forming a light shading layer on the pixel definition layer; forming in the light shading layer and the pixel definition layer a pixel definition aperture exposing the anode; forming an OLED functional layer on the exposed anode; and forming a cathode on the light shading layer and the OLED functional layer.

In an embodiment, the formation of the thin film transistor on the substrate comprises: forming an active layer on the substrate; forming a first insulating layer on the active layer; forming a gate electrode on the first insulating layer; forming a second insulating layer on the gate electrode, the active layer and the substrate; and forming on the second insulating layer a source electrode and a drain electrode, each of the source electrode and the drain electrode penetrating the second insulating layer to be connected to the active layer, wherein the flat layer is disposed on the source electrode, the drain electrode and the second insulating layer, and the anode penetrates the flat layer to be connected to the drain electrode.

In an embodiment, the formation of the OLED functional layer on the exposed anode comprises: forming on the exposed anode a hole generation layer, a hole transport layer, an organic light emitting layer, an electron transport layer, and an electron injection layer stacked in order.

In embodiment, the method further comprises forming a cover on the cathode on light shading layer.

In embodiment, the formation of the light shading layer on the pixel definition layer comprises forming the light shading layer on the pixel definition layer with a black resin.

The adventures effect of the present application: By forming the shielding layer on the pixel definition layer, the light leakage of the OLED functional layer at the side thereof in the pixel definition aperture can be shielded. As such, the problem of light leakage of the pixel in the prior art can be eliminated and the display effect of the display panel can be improved.

### BRIEF DESCRIPTION OF THE DRAWINGS

Accompanying drawings are for providing further understanding of embodiments of the disclosure. The drawings form a part of the disclosure and are for illustrating the principle of the embodiments of the disclosure along with the literal description. Apparently, the drawings in the description below are merely some embodiments of the disclosure, a person skilled in the art can obtain other drawings according to these drawings without creative efforts. In the figures:

FIG. 1 is a schematic view of a display panel in an embodiment according to the present application; and

FIGS. 2A to 2K are schematic views illustrating a method for manufacturing a display panel in an embodiment according to the present application.

### DETAILED DESCRIPTION OF PREFERRED EMBODIMENTS

In order to understand the above objectives, features and advantages of the present disclosure more clearly, the present disclosure is described in detail below with references to the accompanying drawings and specific embodiments.

For clarity, the thickness of layers and regions is exaggerated. In the description and drawings, the same or similar elements are denoted by the same reference numerals.

In should be noted that, in the case of an element, such as a layer, a film, a region or a base and the like, is “on” another element, it means “directly on without an intervening element” or “on with an intervening element.”

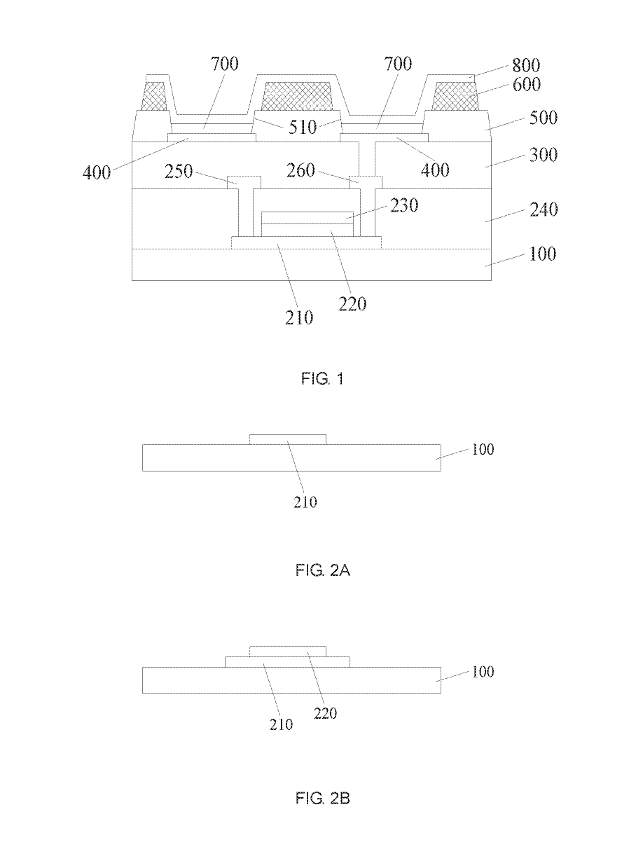

FIG. 1 is a schematic view of a display panel in an embodiment according to the present application. Two anodes are shown in FIG. 1, and one of the anodes is connected to the thin film transistor. It should be noted that each of the anodes in the display panel is connected to the thin film transistor.

Referring to FIG. 1, which illustrated a display panel in an embodiment according to the present application, the display panel comprises a substrate 100, an active layer 210, a first insulating layer 220, a gate electrode 230, a second insulating layer 240, a source electrode 250, a drain electrode 260, a flat layer 300, an anode 400, a pixel definition layer 500, a light shading layer 600, an OLED functional layer 700, a cathode 800 and a cover 900.

In an embodiment, the substrate 100 can be, such as a flexible substrate. The present application is not limited to this embodiment.

The active layer 210 is disposed on the substrate 100. In an embodiment, the active layer 210 can be made of, such as amorphous silicon, low temperature polysilicon, IGZO and the like. The present application is not limited to this embodiment. The first insulating layer 220 is disposed on the active layer 210. The gate electrode 230 is disposed on the first insulating layer 220. The second insulating layer 240 is disposed on the gate electrode 230, the active layer 210 and the substrate 100. The source electrode 250 and the drain electrode 260 are disposed on the second insulating layer 240, and each of the source electrode 250 and the drain electrode 260 penetrates the second insulating layer 240 to be connected to the active layer 210.

In an embodiment, the thin film transistor includes the active layer 210, the first insulating layer 220, the gate electrode 230, the second insulating layer 240, the source electrode 250, and the drain electrode 260. The present application is not limited to this embodiment.

The flat layer 300 is disposed on the second insulating layer 240, the source electrode 250 and the drain electrode 260. The anode 400 is disposed on the flat layer 300 and protrudes the flat layer 300 to be connected to the drain electrode 260. In an embodiment, the anode 400 has high reflectivity.

The pixel definition layer 500 is disposed on the anode 400 and the flat layer 300. The light shading layer 600 is disposed on the pixel definition layer 500. A pixel definition aperture 510 is in the pixel definition layer 500 and the light shading layer 600 for exposing the anode 400.

The OLED functional layer 700 is disposed on the exposed anode 400, In an embodiment, the OLED functional layer 700 includes, in order from the bottom: a hole generation layer, a hole transport layer, an organic emitting layer, an electron transport layer, and an electron injection layer. The present application is not limited to this embodiment.

The cathode 800 is disposed on the pixel definition layer 500, the light shading layer 600 and the OLED functional layer 700. In an embodiment, the cathode 800 has high transmittance. The present application is not limited to this embodiment.

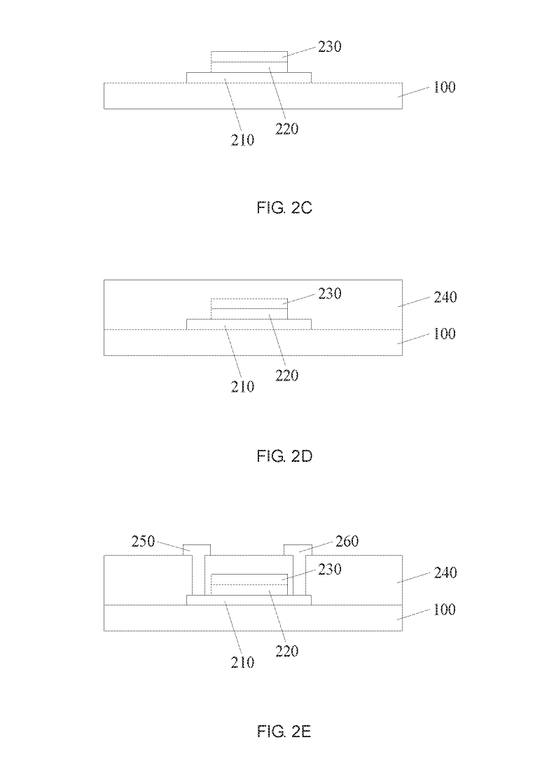

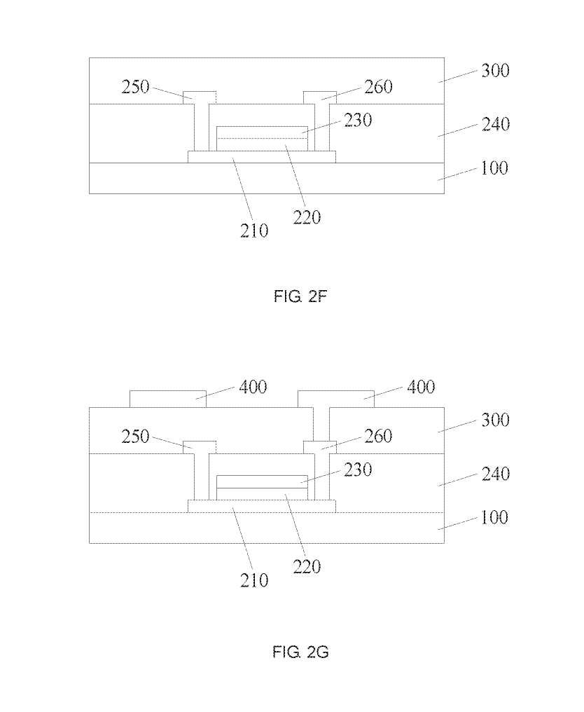

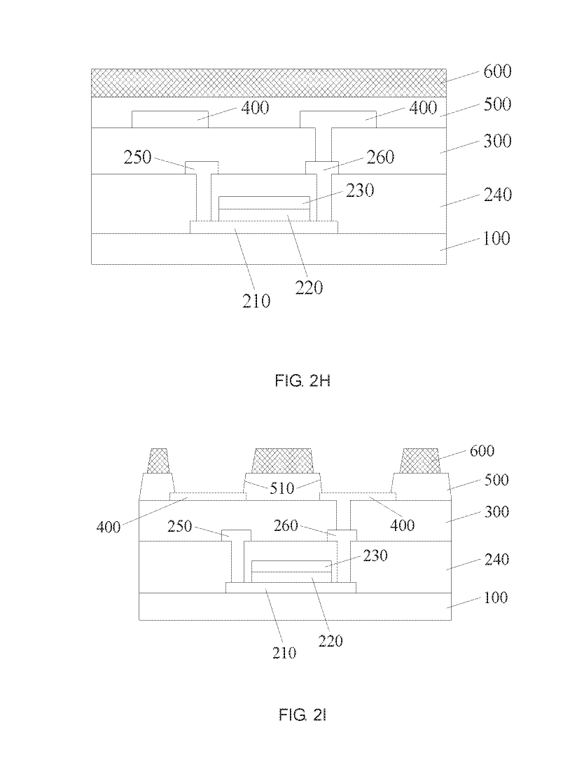

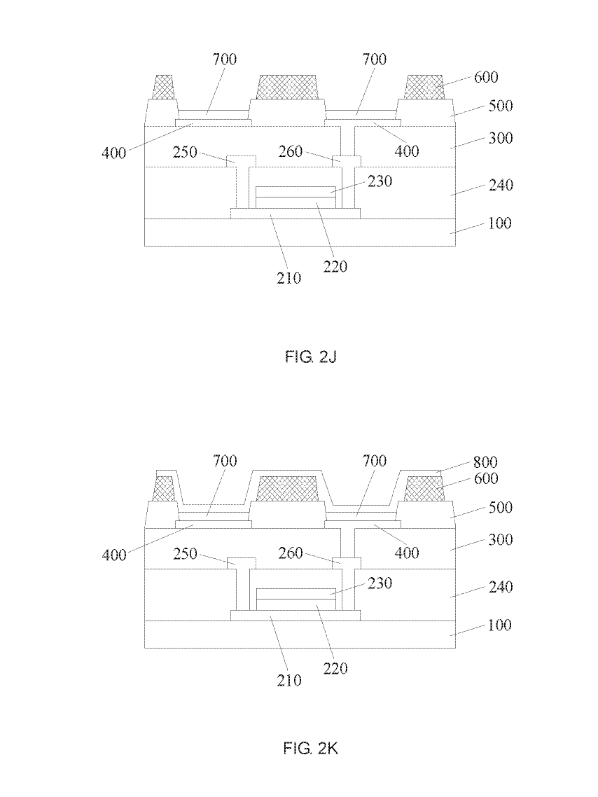

FIGS. 2A to 2K are schematic views illustrating a method for manufacturing a display panel in an embodiment according to the present application.

In an embodiment according to the present application, the method for manufacturing a display panel comprises steps as following.

Step 1: referring FIG. 2A, an active layer 210 is formed on the substrate 100. In an embodiment, the active layer 210 can be made of, such as amorphous silicon, low temperature polysilicon, IGZO and the like. The present application is not limited to this embodiment.

Step 2: referring FIG. 2B, a first insulating layer 220 is formed on the active layer 210.

Step 3: referring FIG. 20, a gate electrode 230 is formed on the first insulating layer 220.

Step 4: referring to FIG. 20, a second insulating layer 240 is formed on the gate electrode 230, the active layer 210 and the substrate 100.

Step 5: referring to FIG. 2E, a source electrode 250 and a drain electrode 260 are formed on the second insulating layer 240, Each of the source electrode 250 and the drain electrode 260 penetrates the second insulating layer 240 to be connected to the active layer 210.

In an embodiment, the thin film transistor is formed by above steps 1 to 5. The present application is not limited to this embodiment.

Step 6: referring to FIG. 2F, a flat layer 300 is formed on the second insulating layer 240, the source electrode 250 and the drain electrode 260.

Step 7: referring to FIG. 2G, an anode 400 is formed on the flat layer 300 and penetrates the flat layer 300 to be connected to the drain electrode 260. In an embodiment, the anode 400 has high reflectivity.

Step 8: referring to FIG. 2H, a pixel definition layer 500 and a light shading layer 600 stacked thereon are formed on the anode 400 and the flat layer 300.

Step 9: referring to FIG. 2I, a pixel definition aperture 510 is formed in the pixel definition layer 500 and the light shading layer 600 for exposing the node 400.

Step 10: referring to FIG. 2J, an OLED functional layer 700 is disposed on the exposed anode 400. In an embodiment, a method of the formation of the OLED functional layer 700 comprises: a hole generation layer, a hole transport layer, an organic light emitting layer, an electron transport layer, and an electron injection layer are formed on the exposed anode 400 in order. The present application is not limited to this embodiment.

Step 11: referring to FIG. 2K, a cathode 800 is formed on the pixel definition layer 500, the light shading layer 600 and the OLED functional layer 700. In an embodiment, the cathode 800 has high transmittance. The present application is not limited to this embodiment.

From the foregoing, in embodiments according to the present application, by forming the shielding layer on the pixel definition layer, the light leakage of the OLED functional layer at the side thereof in the pixel definition aperture can be shielded. As such, the problem of light leakage of the pixel in the prior art can be eliminated and the display effect of the display panel can be improved.

The foregoing contents are detailed description of the disclosure in conjunction with specific preferred embodiments and concrete embodiments of the disclosure are not limited to these description. For the person skilled in the art of the disclosure, without departing from the concept of the disclosure, simple deductions or substitutions can be made and should be included in the protection scope of the application.

What is claimed is:

1. A display panel, comprising:
a substrate;
a thin film transistor disposed on the substrate;
a flat layer disposed on the thin film transistor;
an anode disposed on the flat layer and penetrating the flat layer to be connected to the thin film transistor;
a pixel definition layer disposed on the flat layer;
a light shading layer disposed on the pixel definition layer, wherein the light shading layer and the pixel definition layer have a pixel definition aperture in the light shading layer and the pixel definition layer for exposing the anode;
an OLED functional layer disposed on the exposed anode; and
a cathode disposed on the light shading layer and the OLED functional layer.

2. The display panel according to claim 1, wherein the thin film transistor comprises:
an active layer disposed on the substrate;
a first insulating layer disposed on the active layer;
a gate electrode disposed on the first insulating layer;
a second insulating layer disposed on the gate electrode, the active layer and the substrate; and
a source electrode and a drain electrode disposed on the second insulating layer, each of the source electrode and the drain electrode penetrating the second insulating layer to be connected to the active layer, wherein the flat layer is disposed on the source electrode, the drain electrode and the second insulating layer, and the anode penetrates the flat layer to be connected to the drain electrode.

3. The display panel according to claim 1, wherein the OLED functional layer includes in order form the anode to the cathode: a hole generation layer, a hole transport layer, an organic light emitting layer, an electron transport layer and an electron injection layer.

4. The display panel according to claim 2, wherein the OLED functional layer includes in order form the anode to the cathode: a hole generation layer, a hole transport layer, an organic light emitting layer, an electron transport layer and an electron injection layer.

5. The display panel according to claim 1, further comprises a cover disposed on the cathode on the light shading layer.

6. The display panel according to claim 1, wherein the light shading layer is made of a black resin.

7. A method for manufacturing a display panel, comprising:
forming a thin film transistor on a substrate;
forming a flat layer on the thin film transistor;
forming on the flat layer an anode penetrating the flat layer to be connected to the thin film transistor;
forming a pixel definition layer on the flat layer and the anode;
forming a light shading layer on the pixel definition layer;
forming in the light shading layer and the pixel definition layer a pixel definition aperture exposing the anode;
forming an OLED functional layer on the exposed anode; and
forming a cathode on the light shading layer and the OLED functional layer.

8. The method according to claim 7, wherein the formation of the thin film transistor on the substrate comprises:
forming an active layer on the substrate;
forming a first insulating layer on the active layer;
forming a gate electrode on the first insulating layer;
forming a second insulating layer on the gate electrode, the active layer and the substrate; and
forming on the second insulating layer a source electrode and a drain electrode, each of the source electrode and the drain electrode penetrating the second insulating layer to be connected to the active layer,
wherein the flat layer is disposed on the source electrode, the drain electrode and the second insulating layer, and the anode penetrates the flat layer to be connected to the drain electrode.

9. The method according to claim 7, wherein the formation of the OLED functional layer on the exposed anode comprises: forming on the exposed anode a hole generation layer, a hole transport layer, an organic light emitting layer, an electron transport layer, and an electron injection layer stacked in order.

10. The method according to claim 8, wherein the formation of the OLED functional layer on the exposed anode comprises: forming on the exposed anode a hole generation layer, a hole transport layer, an organic light emitting layer, an electron transport layer, and an electron injection layer stacked in order.

11. The method according to claim 7, further comprises forming a cover on the cathode on light shading layer.

12. The method according to claim 7, wherein the formation of the light shading layer on the pixel definition layer comprises forming the light shading layer on the pixel definition layer with a black resin.
